(19) United States
(12) Patent Application Publication
(10) Pub. No.: US 2016/0172615 A1
(43) Pub. Date: Jun. 16, 2016

(54) ORGANIC LIGHT EMITTING DISPLAY

(71) Applicant: LG DISPLAY CO., LTD., Seoul (KR)

(72) Inventors: Hyunsuk KIM, Paju-si (KR); Kyuil HAN, Paju-si (KR); Namseok YOO, Seoul (KR)

(21) Appl. No.: 14/968,158

(22) Filed: Dec. 14, 2015

(30) Foreign Application Priority Data
Dec. 15, 2014 (KR) 10-2014-0180478

(51) Int. Cl. H01L 51/50; C09K 11/02; C09K 11/06

(52) U.S. Cl. CPC H01L 51/5028; H01L 51/5016; C09K 11/06; C09K 11/02; H01L 2251/5376; H01L 2251/5384; H01L 51/0072

(57) ABSTRACT

An organic light emitting display is disclosed. The organic light emitting display includes an emission layer formed between two electrodes positioned on a substrate. The emission layer includes a host of fluorescent materials and a dopant of phosphorescent materials. A host photoluminescence (PL) region formed by the host of the fluorescent materials indicates a spectrum overlapping a MLCT3 (metal-to-ligand charge transfer: MLCT) region of a dopant ultraviolet (UV) absorption region formed by the dopant of the phosphorescent materials.

This application claims the benefit of Korean Patent Application No. 10-2014-0180478 filed on Dec. 15, 2014, which is incorporated herein by reference for all purposes as if fully set forth herein.

### BACKGROUND OF THE INVENTION

1. Field of the Invention

Embodiments of the invention relate to an organic light emitting display.

2. Description of the Related Art

An organic light emitting element used in an organic light emitting display is a self-emission element in which an emission layer is formed between two electrodes positioned on a substrate.

The organic light emitting display may be classified into a top emission type, a bottom emission type, and a dual emission type depending on an emission direction of light.

The organic light emitting display adopts a method of implementing an image using organic light emitting elements emitting red, green, and blue light and a method of implementing an image using an organic light emitting element emitting white light and red, green, and blue color filters.

A light emitting material of the organic light emitting display may maximize a performance using a host-dopant system. In this instance, an important factor is smooth energy transition from the host to the dopant.

Energy transition attributable to dipole-dipole interactions is chiefly generated in fluorescent materials, and energy transition attributable to mutual exchange of electrons is chiefly generated in phosphorescent materials. However, if the energy transition attributable to the dipole-dipole interactions is generated in the phosphorescent materials, the energy transition is not smoothly performed due to a complicated energy level. Hence, problems of a narrow viewing angle and low efficiency are generated due to changes in electroluminescence (EL) spectrum, and there is a need to address the problems.

### SUMMARY OF THE INVENTION

In one aspect, there is an organic light emitting display comprising an emission layer formed between two electrodes positioned on a substrate, the emission layer including a host of fluorescent materials and a dopant of phosphorescent materials, wherein a host photoluminescence (PL) region formed by the host of the fluorescent materials indicates a spectrum overlapping a MLCT3 (metal-to-ligand charge transfer: MLCT) region of a dopant ultraviolet (UV) absorption region formed by the dopant of the phosphorescent materials.

In another aspect, there is an organic light emitting display comprising an emission layer formed between two electrodes positioned on a substrate, the emission layer including at least two hosts of fluorescent materials and a dopant of phosphorescent materials, wherein a host A photoluminescence (PL) region formed by a host A of the fluorescent materials indicates a spectrum overlapping a MLCT3 (metal-to-ligand charge transfer: MLCT) region of a dopant ultraviolet (UV) absorption region formed by the dopant of the phosphorescent materials, and wherein a host B PL region formed by a host B of the fluorescent materials indicates a spectrum overlapping a MLCT1 region of the dopant UV absorption region formed by the dopant of the phosphorescent materials.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a schematic plane view of an organic light emitting display;

FIG. 2 is an example of a circuit configuration of a subpixel shown in FIG. 1;

FIG. 3 is an exemplary cross-sectional view of a subpixel shown in FIG. 1;

FIG. 4 is a diagram illustrating a method of forming an emission layer;

FIG. 5 is a cross-sectional hierarchy diagram of the emission layer formed using the method of FIG. 4;

FIG. 6 is a graph illustrating measured values of sharpness at each wavelength in a related art display panel implemented using a phosphorescent dopant;

FIG. 7 is a diagram illustrating energy transition attributable to dipole-dipole interactions between a host and a dopant;

FIG. 8 is a graph illustrating measured values of sharpness at each wavelength in a display panel implemented using a phosphorescent dopant according to a first embodiment of the invention;

FIG. 9 is a graph illustrating an EL spectrum for a comparison between a related art display panel and a display panel according to the first embodiment of the invention;

FIGS. 10A and 10B are graphs illustrating viewing angles for a comparison between a related art display panel and a display panel according to the first embodiment of the invention;

FIG. 11 is a graph illustrating a difference between viewing angles depending on the characteristics of host materials; and

FIG. 12 is a graph illustrating measured values of sharpness at each wavelength in a display panel implemented using a phosphorescent dopant according to a second embodiment of the invention.

### DETAILED DESCRIPTION OF THE ILLUSTRATED EMBODIMENTS

Reference will now be made in detail to embodiments of the invention, examples of which are illustrated in the accompanying drawings. Wherever possible, the same reference numbers will be used throughout the drawings to refer to the same or like parts. It will be paid attention that detailed description of known arts will be omitted if it is determined that the arts can mislead the embodiments of the invention.

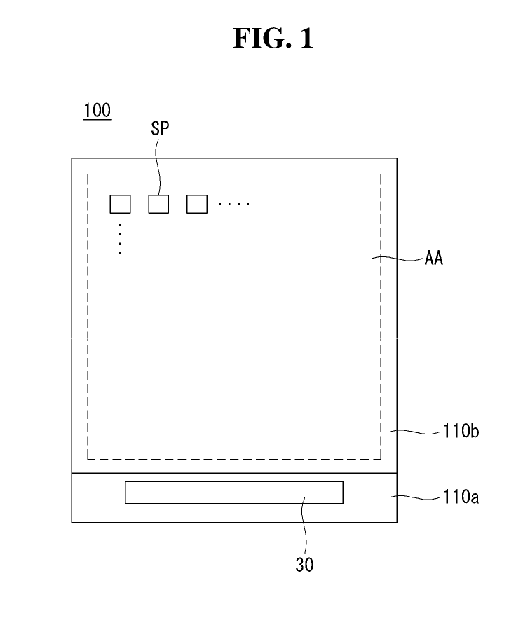

Exemplary embodiments of the invention will be described with reference to FIGS. 1 to 12.

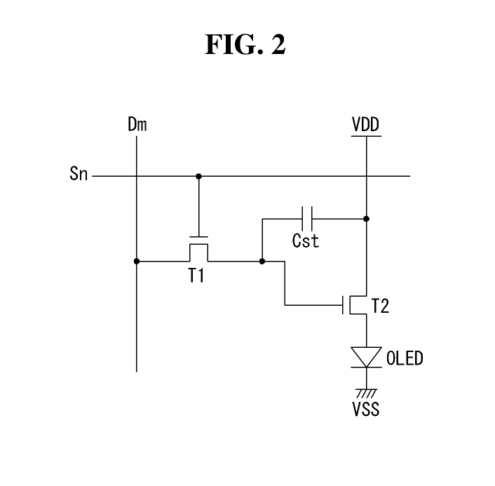

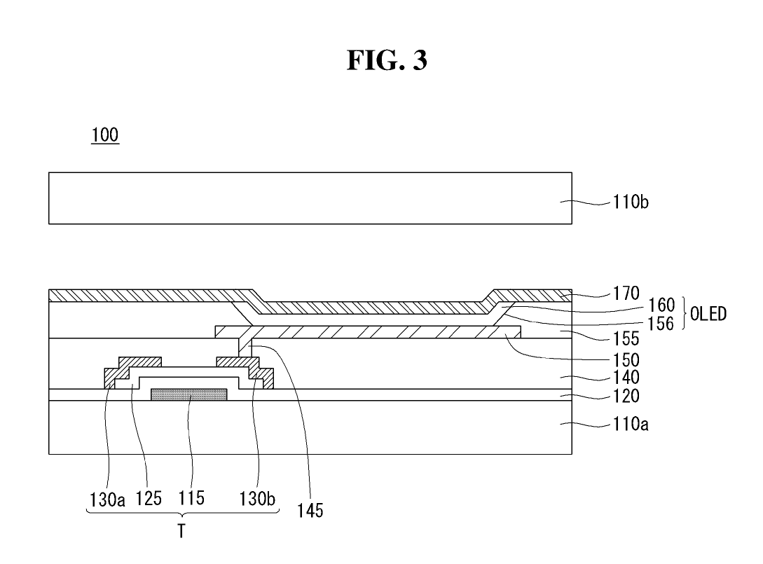

FIG. 1 is a schematic plane view of an organic light emitting display, FIG. 2 is an example of a circuit configuration of a subpixel shown in FIG. 1, and FIG. 3 is an exemplary cross-sectional view of a subpixel shown in FIG. 1.

As shown in FIG. 1, a display panel 100 constituting an organic light emitting display includes a display unit AA including a plurality of subpixels SP formed on a first substrate 110a. The display unit AA formed on the first substrate 110a is sealed by a second substrate 110b.

A driver 30 is formed on the first substrate 110a and drives the plurality of subpixels SP included in the display unit AA. The driver 30 may include a data driver supplying a data signal to the plurality of subpixels SP and a scan driver supplying a scan signal to the plurality of subpixels SP. The scan driver may be separated from the data driver and may be positioned outside the display unit AA in a gate-in-panel (GIP) manner.

As shown in FIG. 2, the subpixel SP may include a switching thin film transistor T1 transmitting the data signal supplied through a data line Dm in response to the scan signal supplied through a scan line Sn, a capacitor Cst storing the data signal, a driving thin film transistor T2 generating a driving current corresponding to a difference between the data signal stored in the capacitor Cst and a first power voltage VDD, and an organic light emitting diode (OLED) emitting light corresponding to the driving current.

The switching thin film transistor T1, the capacitor Cst, and the driving thin film transistor T2 may be defined as a transistor unit. The transistor unit has been illustrated as being a so-called 2T1C type including two thin film transistors and a single capacitor, as an example. In some embodiments, the transistor unit may be configured to include N (N is an integer equal to or greater than 2) thin film transistors and M (M is an integer equal to or greater than 2) capacitors in order to compensate for a threshold voltage, etc. In FIG. 2, VSS is a second power voltage equal to or less than a ground level voltage.

The subpixels SP are driven through a method of implementing an image using OLEDs emitting red, green, and blue light and a method of implementing an image using an OLED emitting white light and red, green, and blue color filters. In the following description, the subpixels driven through the method of implementing the image using the OLEDs emitting red, green, and blue light are used as an example.

As shown in FIG. 3, the transistor unit T and the OLED included in the subpixel are deposited on the first substrate 110a in a thin film form.

A gate electrode 115 is formed on the first substrate 110a. The gate electrode 115 may be made of one selected from the group consisting of molybdenum (Mo), aluminum (Al), chromium (Cr), gold (Au), titanium (Ti), nickel (Ni), and copper (Cu) or an alloy thereof. The gate electrode 115 may have a single-layered structure or a multi-layered structure.

A first insulating layer 120 for insulating the gate electrode 115 is formed on the gate electrode 115. The first insulating layer 120 may be a silicon oxide (SiOx) layer, a silicon nitride (SiNx) layer, or a dual layer of them.

A semiconductor layer 125 is formed on the first insulating layer 120 corresponding to the gate electrode 115. The semiconductor layer 125 may be made of amorphous silicon (a-Si), poly-Si, oxide, or an organic material, etc.

A source electrode 130a and a drain electrode 130b are formed on the semiconductor layer 125 and are electrically connected to the semiconductor layer 125. The source electrode 130a and the drain electrode 130b may be made of one selected from the group consisting of molybdenum (Mo), aluminum (Al), chromium (Cr), gold (Au), titanium (Ti), nickel (Ni), and copper (Cu) or an alloy thereof. Each of the source electrode 130a and the drain electrode 130b may have a single-layered structure or a multi-layered structure. An ohmic contact layer may be formed between the semiconductor layer 125 and the source electrode 130a and between the semiconductor layer 125 and the drain electrode 130b to reduce a contact resistance between them.

A second insulating layer 140 is formed on the thin film transistor T including the gate electrode 115, the semiconductor layer 125, the source electrode 130a, and the drain electrode 130b. The second insulating layer 140 may be a planarization layer or a passivation layer for reducing the step coverage of an underlying structure. The second insulating layer 140 may be made of an organic material, such as polyimide, benzocyclobutene-based resin, or acrylate. The second insulating layer 140 includes a via hole 145 through which a portion of the source electrode 130a or the drain electrode 130b is exposed.

A lower electrode 150 is formed on the second insulating layer 140 and is electrically connected to the source electrode 130a or the drain electrode 130b. The lower electrode 150 may be a transparent conductive film made of Indium Tin Oxide (ITO), Indium Zinc Oxide (IZO), Indium Tin Zinc Oxide (ITZO), Zinc Oxide (ZnO), Indium Gallium Zinc Oxide (IGZO), or graphene. The lower electrode 150 may function as an anode electrode.

A bank layer 155 is formed on the lower electrode 150 and includes an opening 156 through which the lower electrode 150 is exposed. The bank layer 155 may be a pixel definition layer that mitigates the step coverage of an underlying structure and defines an emission region. The bank layer 155 may be made of polyimide, benzocyclobutene-based resin, or acrylate.

An organic emission layer 160 is formed on the lower electrode 150. The organic emission layer 160 may be made of an organic material that emits red, green, and blue light. The organic emission layer 160 may include an emission layer EML and four common layers including a hole injection layer (HIL), a hole transport layer (HTL), an electron transport layer (ETL), and an electron injection layer (EIL) for improving characteristics of the emission layer (EML). The common layers may not include all the four layers. In some embodiments, at least one of the four common layers may be omitted, combined together, or at least one other functional layer may be further included in the common layer.

An upper electrode 170 is formed on the first substrate 110a including the organic emission layer 160. The upper electrode 170 may be made of a metal having a low work function, for example, aluminum (Al), silver (Ag), magnesium (Mg), and calcium (Ca), or an alloy thereof. The upper electrode 170 may function as a cathode electrode. The elements (i.e., the transistor unit, the OLED, etc.) formed on the first substrate 110a are sealed by the second substrate 110b (or other sealing means or encapsulation structure) and thus are protected from moisture and/or oxygen.

The subpixels formed on the display panel 100 have been illustrated as adopting a bottom-emission method in which light is emitted in the direction of the first substrate 110a, but embodiments of the invention are not limited thereto. In some embodiments, the subpixels may be configured to adopt a top emission method or a dual emission method.

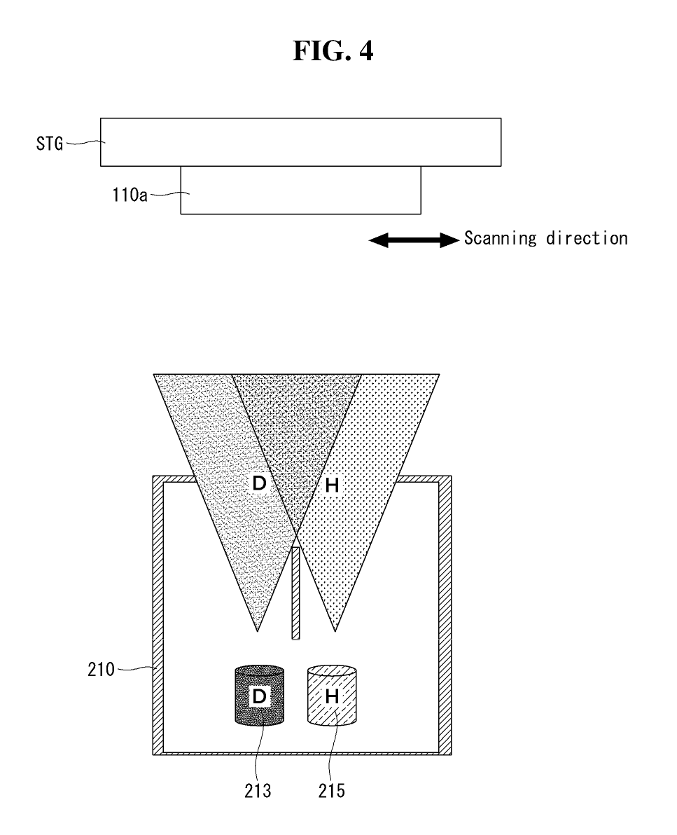

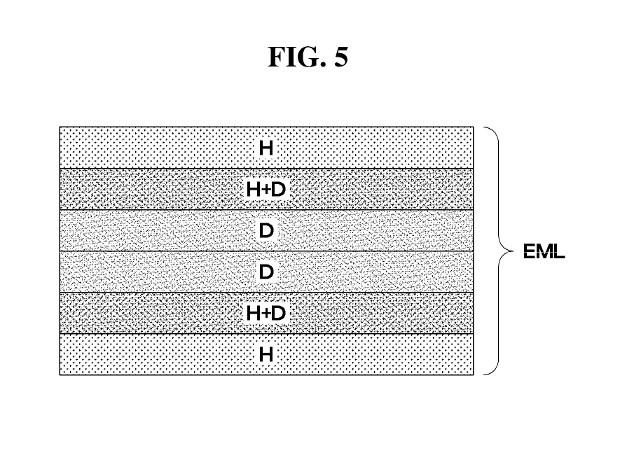

FIG. 4 is a diagram illustrating a method of forming the emission layer, and FIG. 5 is a cross-sectional hierarchy diagram of the emission layer formed using the method of FIG. 4.

As shown in FIG. 4, the emission layer of the OLED is formed using a method of simultaneously depositing a host and a dopant. An organic source unit 210 may be disposed under a deposition device.

A first source unit 213 that provides a dopant material D and a second source unit 215 that provides a host material H can be part of the organic source unit 210. The first source unit 213 and the second source unit 215 of the organic source unit 210 are physically separated from each other, but the dopant and host materials D and H have a certain overlap area when they pass through the organic source unit 210 and travel in a target direction.

A stage STG moves over, i.e., along the top of, the organic source unit 210 as if the stage STG scans an upper part of the organic source unit 210 in a state where the stage STG holds the first substrate 110a, which has the underlying electrodes of the transistor unit and the OLED already formed thereon.

The stage STG may move with respect to the organic source unit 210 as if the stage STG performs the scanning operation from right to left, but is not limited thereto. For example, the stage STG may move in one direction (e.g., move from right to left) as if the stage STG performs scanning or may move in both directions (e.g., move from right to left and then move from left to right) as if the stage STG performs scanning.

The hierarchy of the host and the dopant, which form the emission layer of the OLED, may have various forms depending on the number of times of scanning movement of the stage STG.

As shown in FIG. 5, the emission layer EML of the OLED may have a hierarchy including a host region H, a mixture region H+D of the host and dopant materials H and D, a dopant region D, a dopant region D, a mixture region H+D of the host and dopant materials H and D, and a host region H, which are sequentially deposited from the bottom to the top in the order mentioned above.

The hierarchy structure of the emission layer EML of the OLED shown in FIG. 5 is obtained when the stage once performs a bidirectional scanning process, in which the stage moves from right to left and then returns to the right. In general, when the host material H and the dopant material D are simultaneously deposited, the emission layer EML is divided into the dopant region D, the host region H, and the mixture region H+D. Namely, a single region, such as the dopant region D and the host region H, other than the mixture region H+D is included in the emission layer EML.

If the single region, such as the dopant region D and the host region H, is present, a distance between the host and the dopant increases and energy transition attributable to dipole-dipole interactions are generated when phosphorescent materials are used. Problems related to an increase in the distance and the energy transition attributable to the dipole-dipole interactions and a solution to such are described later.

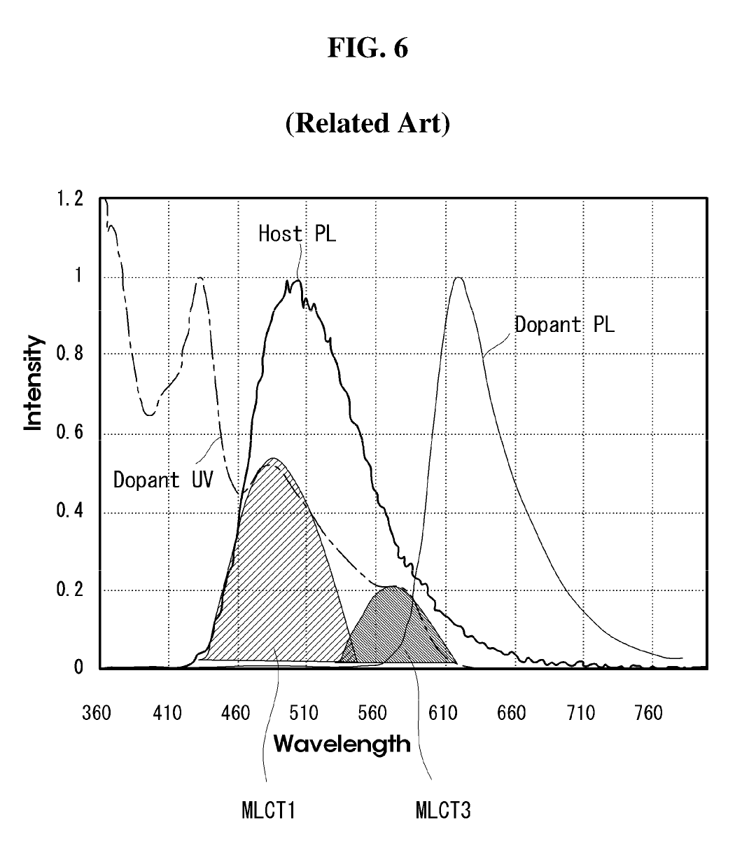

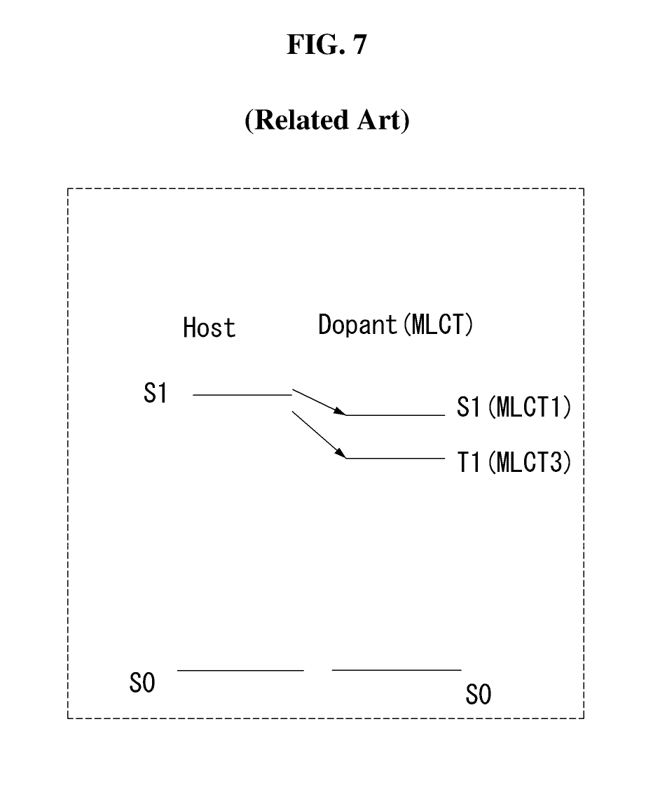

FIG. 6 is a graph illustrating measured values of sharpness at each wavelength in a related art display panel implemented using a phosphorescent dopant, and FIG. 7 is a diagram illustrating energy transition attributable to dipole-dipole interactions between a host and a dopant. In FIG. 6, a horizontal axis denotes the wavelength of light, and a vertical axis denotes sharpness or intensity.

As shown in FIGS. 6 and 7, in the related art display panel implemented using a phosphorescent dopant, metal-to-ligand charge transfer (MLCT) regions (MLCT1 and MLCT3) in a dopant UV absorption region (Dopant UV) are present inside a host photoluminescence (PL) region (Host PL). The MLCT region means a region where dipole energy transition, in which charges move from the full metal orbital of the host to the empty ligand orbital of the dopant, may occur. The MLCT1 region is the region of a singlet S1, and the MLCT3 region is the region of a triplet T1.

The dipole energy transition occurs when the host PL region Host PL and the dopant UV absorption region Dopant UV overlap each other in an ultraviolet (UV) region and PL spectra. Because the overlap between the host PL region Host PL and the dopant UV absorption region Dopant UV is generated in only one of the MLCT1 region and the MLCT3 region in fluorescent materials, the dipole energy transition is generated in only one of the MLCT1 region and the MLCT3 region. On the other hand, because the overlap between the host PL region Host PL and the dopant UV absorption region Dopant UV is generated in both the MLCT1 region and the MLCT3 region in phosphorescent materials, the dipole energy transition is generated in both the MLCT1 region and the MLCT3 region. Namely, it has been theoretically known that the dipole energy transition may occur when the host PL region Host PL overlaps the MLCT1 region or the MLCT3 region in the dopant UV absorption region Dopant UV or when the host PL region Host PL overlaps both the MLCT1 region and the MLCT3 region.

However, an experiment revealed that the energy transition is rarely generated when the host PL region Host PL overlaps both the MLCT1 region and the MLCT3 region of the dopant UV absorption region Dopant UV. For this reason, if the host PL emits light in a region where the efficiency is reduced or the energy transition is rarely generated, changes in an electroluminescence (EL) spectrum are generated and lead to a reduction in viewing angle characteristics of the display panel.

To address such problems, the embodiment of the invention causes the host PL region Host PL to overlap only the MLCT3 region in the phosphorescent dopant UV absorption Dopant UV based on the result of the above-described experiment, thereby improving the characteristics of the organic light emitting display. This is described below.

### First Embodiment

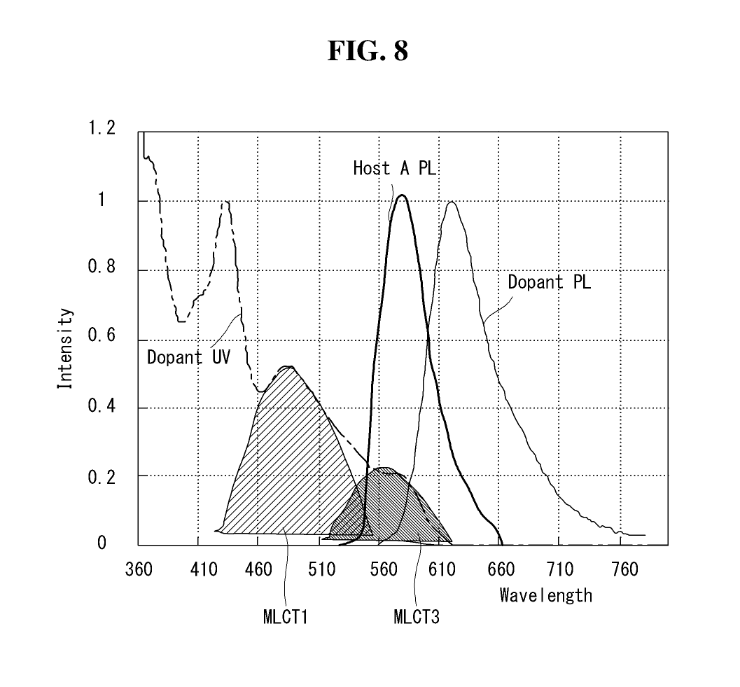

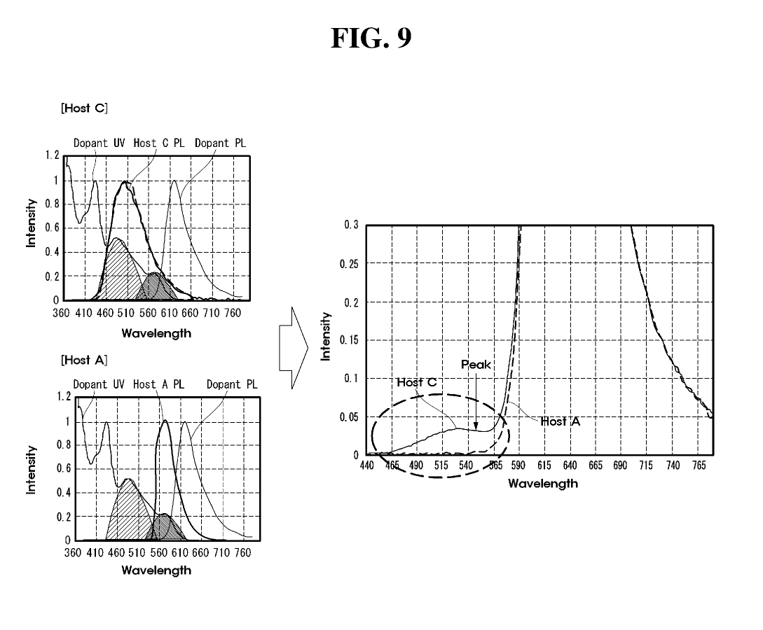

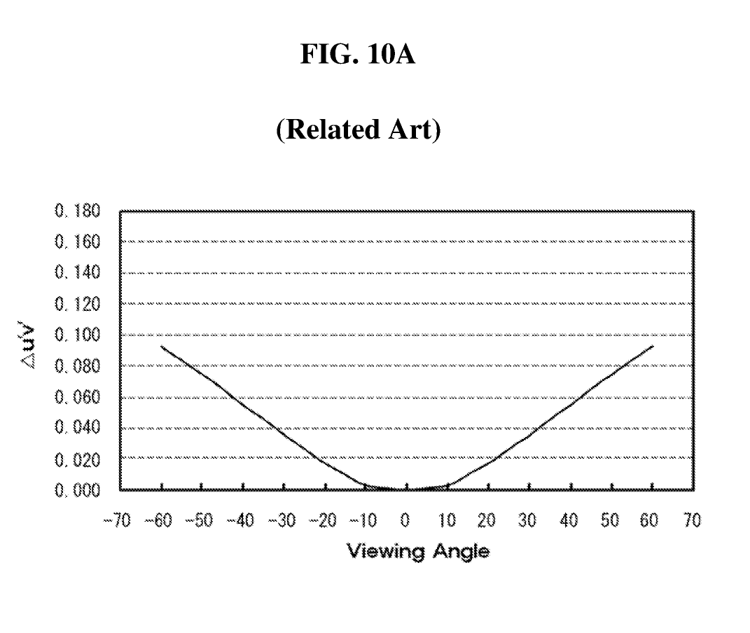

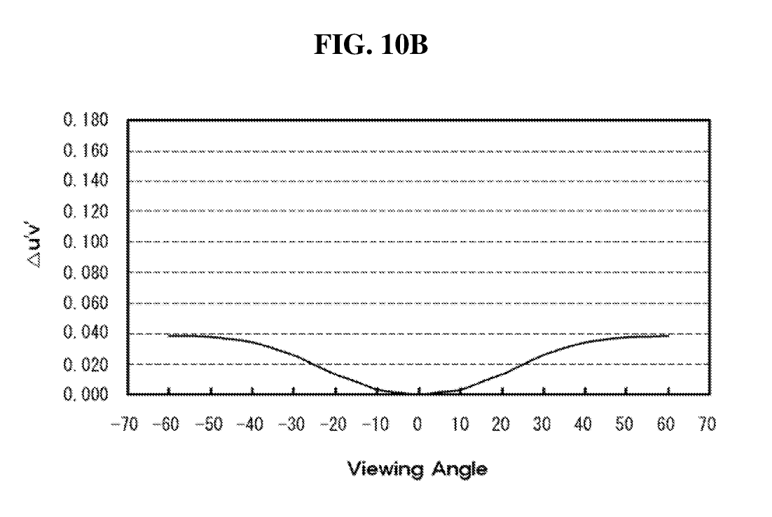

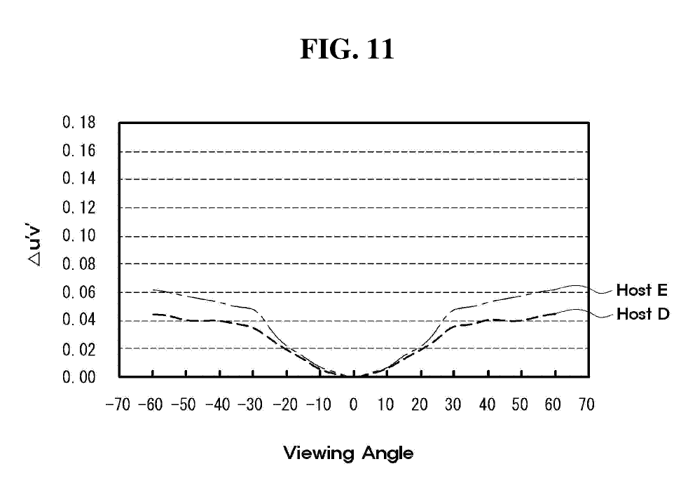

FIG. 8 is a graph illustrating measured values of (intensity or) sharpness of each wavelength in a display panel implemented using a phosphorescent dopant according to a first embodiment of the invention. FIG. 9 is a graph illustrating an EL spectrum for a comparison between a related art display panel and the display panel according to the first embodiment of the invention. FIGS. 10A and 10B are graphs illustrating viewing angles for a comparison between the related art display panel and the display panel according to the first embodiment of the invention. FIG. 11 is a graph illustrating a difference between viewing angles depending on the characteristics of host materials. In FIGS. 8 and 9, a horizontal axis denotes the wavelength of light, and a vertical axis denotes sharpness or intensity.

As shown in FIG. 8, in the first embodiment of the invention, the MLCT3 region is present in a host A PL region Host A PL, and the MLCT1 region is not present in the host A PL region Host A PL. Namely, the host A PL region Host A PL overlaps the MLCT3 region, but does not overlap the MLCT1 region.

However, because the MLCT1 region and the MLCT3 region partially overlap each other, only a portion of the MLCT1 region is present in the host A PL region Host A PL. More specifically, the host A PL region Host A PL overlaps the peak of the MLCT3 region, but does not overlap the peak of the MLCT1 region. Further, the host A PL region Host A PL overlaps a dopant PL region Dopant PL, but does not overlap the peak of the dopant PL region Dopant PL.

The first embodiment of the invention causes only the MLCT3 region to be present in the host A PL region Host A PL by changing the structure of the emission layer including a host material and shifting a wavelength band occupied by the host A PL region Host A PL. In the embodiment disclosed herein, the host used in the experiment is fluorescent materials formed of, for example, carbazole-based compound, and the dopant used in the experiments is, for example, phosphorescent materials. Furthermore, the dopant of the phosphorescent materials has a PL wavelength band of 380 nm to 780 nm.

As shown in FIG. 9, a host C PL region Host C PL of a host C material Host C used in the related art display panel overlaps both the MLCT1 region and the MLCT3 region of the dopant. For this reason, an EL peak of the host C material Host C is generated in the host region as in a graph on the right side in FIG. 9.

On the other hand, as shown in FIG. 9, in a host A material Host A used in the display panel according to the first embodiment of the invention, the host A PL region Host A PL overlaps only the MLCT3 region of the dopant. For this reason, an EL peak of the host A material Host A is not generated in the host region as in the graph on the right side.

A comparison and an experiment were performed on efficiency of the host C material Host C used in the related art display panel and efficiency of the host A material Host A used in the display panel according to the first embodiment of the invention, thereby obtaining the following data, such as that in Table 1 below.

TABLE 1

| | Host C | Host A |
|---|---|---|
| Notes | (Related art) | (Present invention) |
| Efficiency (cd/A) | 25 cd/A | 30 cd/A |

Furthermore, a comparison and an experiment were performed on the viewing angle characteristic of the host C material Host C used in the related art display panel and the viewing angle characteristic of the host A material Host A used in the display panel according to the first embodiment of the invention, thereby obtaining the following data, such as that of FIGS. 10A and 10B. In FIGS. 10A and 10B, a horizontal axis denotes a viewing angle, and a vertical axis denotes a color deviation Au′v′ in chromaticity coordinates.

According to Table 1 and FIGS. 10A and 10B, the host C material Host C used in the related art display panel turned yellowish due to the EL peak generated in the host region, thereby reducing the viewing angle characteristic and the efficiency (refer to FIG. 10A). On the other hand, the host A material Host A used in the display panel according to the first embodiment of the invention had the host A PL region Host A PL overlapping only the MLCT3 region, thereby improving the viewing angle characteristic and the efficiency compared to the host C material Host C (refer to FIG. 10B).

An example of the experiment conducted using only the host A material Host A has been described above. However, as can be seen from FIG. 11, the characteristics were obtained by a host D material Host D and a host E material Host E in addition to the host A material Host A.

The experiments conducted using the host A material Host A, the host D material Host D, and the host E material Host E revealed that the color deviation Δu′v′ in the chromaticity coordinates was about 0.04 to 0.06. Each of the host D material Host D and the host E material Host E also had a host PL region overlapping both the MLCT1 region and the MLCT3 region.

It was found that the host D material Host D and the host E material Host E had the improved viewing angle characteristic and the improved efficiency compared to the host C material Host C, but had slightly improved viewing angle characteristic and the slightly improved efficiency compared to the host A material Host A. As can be seen from the experiment, when the host material includes both the MLCT1 region and the MLCT3 region, the improvement of the viewing angle characteristic and the efficiency may be reduced.

As described above, the first embodiment of the invention is advantageous in that it can improve the viewing angle characteristic and the efficiency because the spectrum region of the host is optimized by mixing and using the host of the fluorescent materials and the dopant of the phosphorescent materials and overlapping the host PL region with one of phosphorescent dopant UV absorption regions.

The first embodiment of the invention used the single host of the fluorescent materials. However, N hosts including the fluorescent materials may be mixed and used, where N is an integer equal to or greater than 2. In this instance, an embodiment of the invention for improving the characteristics of the element is described below.

### Second Embodiment

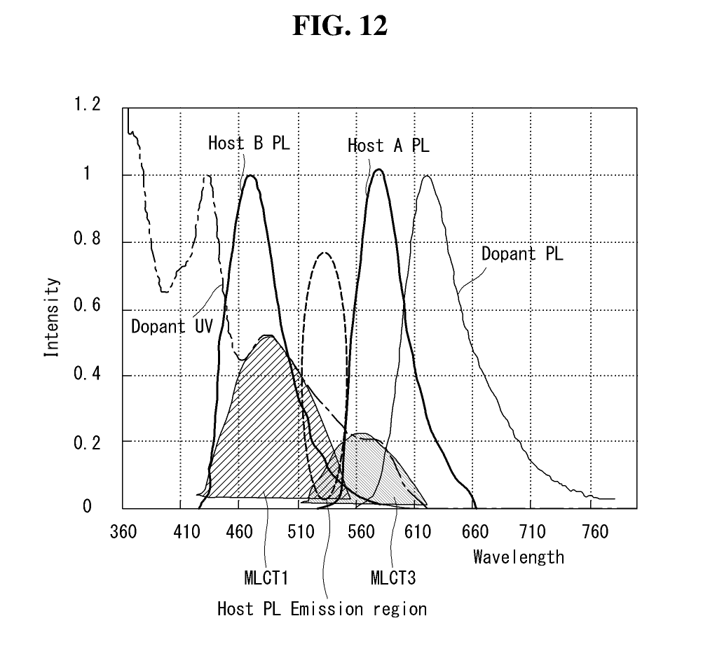

FIG. 12 is a graph illustrating measured values of sharpness (intensity) at each wavelength in a display panel implemented using a phosphorescent dopant according to a second embodiment of the invention.

As shown in FIG. 12, at least two hosts of fluorescent materials according to the second embodiment of the invention are mixed, and host PL regions Host A PL and Host B PL formed by at least two hosts of the fluorescent materials do not overlap a host PL emission region positioned between the host PL regions Host A PL and Host B PL.

For this, MLCT3 region is present in the host A PL region Host A PL, and MLCT1 region is not present in the host A PL region Host A PL. Namely, the host A PL region Host A PL overlaps the MLCT3 region, but does not overlap the MLCT1 region. MLCT1 region is present in the host B PL region Host B PL, and MLCT3 region is not present in the host B PL region Host B PL. Namely, the host B PL region Host B PL overlaps the MLCT1 region, but does not overlap the MLCT3 region.

However, because the MLCT1 region and the MLCT3 region partially overlap each other. Therefore, only a portion of the MLCT1 region is present in the host A PL region Host A PL. More specifically, the host A PL region Host A PL overlaps the peak of the MLCT3 region, but does not overlap the peak of the MLCT1 region. Further, the host A PL region Host A PL overlaps a dopant PL region Dopant PL, but does not overlap the peak of the dopant PL region Dopant PL.

Only a portion of the MLCT3 region is present in the host B PL region Host B PL. More specifically, the host B PL region Host B PL overlaps the peak of the MLCT1 region, but does not overlap the peak of the MLCT3 region.

The host A material Host A forming the host A PL region Host A PL is carbazole-based compound described in the first embodiment of the invention, and a host B material Host B forming the host B PL region Host B PL is anthracene-based compound.

The host PL emission region is present between the MLCT1 region and the MLCT3 region and corresponds to a region where the energy transition between the MLCT1 region and the MLCT3 region is rarely generated. An experiment revealed that the region where the energy transition between the MLCT 1 region and the MLCT3 region is rarely generated has the low efficiency and corresponds to a non-energy transition region. If the host PL emits light in the non-energy transition region, an EL spectrum changes. The changes in the EL spectrum lead to a reduction in viewing angle characteristic of the display panel.

Hence, the second embodiment of the invention is configured so that the host A PL region Host A PL and the host B PL region Host B PL do not overlap the host PL emission region, are separated from the host PL emission region, and respectively overlap the MLCT3 region and the MLCT1 region. Namely, the host A PL region Host A PL and the host B PL region Host B PL overlap each other only in an overlap region between the MLCT1 region and the MLCT3 region.

As described above, the second embodiment of the invention mixes (or combines) and uses at least two hosts of the fluorescent materials and the dopant of the phosphorescent materials and overlaps the two host PL regions in different phosphorescent dopant UV absorption regions, thereby optimizing the spectrum region of the host and improving the viewing angle characteristic and the efficiency of the display panel.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An organic light emitting display, comprising:
an emission layer between two electrodes on a substrate, the emission layer including a host of fluorescent materials and a dopant of phosphorescent materials,
wherein a host photoluminescence (PL) region due to the host of the fluorescent materials indicates a spectrum overlapping a MLCT3 (metal-to-ligand charge transfer: MLCT) region of a dopant ultraviolet (UV) absorption region due to the dopant of the phosphorescent materials.

2. The organic light emitting display of claim 1, wherein the MLCT3 region of the dopant UV absorption region is present in the host PL region, and only a portion of a MLCT1 region of the dopant UV absorption region is present in the host PL region.

3. The organic light emitting display of claim 1, wherein the host PL region overlaps a peak of the MLCT3 region of the dopant UV absorption region and does not overlap a peak of a MLCT1 region of the dopant UV absorption region.

4. The organic light emitting display of claim 1, wherein the host PL region partially overlaps a dopant PL region.

5. The organic light emitting display of claim 1, wherein the host of the fluorescent materials includes a carbazole-based compound.

6. The organic light emitting display of claim 1, wherein the emission layer includes a host region, a mixture region of the host and the dopant, and a dopant region.

7. The organic light emitting display of claim 1, wherein the dopant of the phosphorescent materials has a PL wavelength band of 380 nm to 780 nm.

8. An organic light emitting display, comprising:
an emission layer between two electrodes on a substrate, the emission layer including at least two hosts of fluorescent materials and a dopant of phosphorescent materials,
wherein a host A photoluminescence (PL) region formed by a host A of the fluorescent materials indicates a spectrum overlapping a MLCT3 (metal-to-ligand charge transfer: MLCT) region of a dopant ultraviolet (UV) absorption region formed by the dopant of the phosphorescent materials, and
wherein a host B PL region formed by a host B of the fluorescent materials indicates a spectrum overlapping a MLCT1 region of the dopant UV absorption region formed by the dopant of the phosphorescent materials.

9. The organic light emitting display of claim 8, wherein the MLCT3 region of the dopant UV absorption region is present in the host A PL region, and only a portion of the MLCT1 region of the dopant UV absorption region is present in the host A PL region, and
wherein the MLCT1 region of the dopant UV absorption region is present in the host B PL region, and only a portion of the MLCT3 region of the dopant UV absorption region is present in the host B PL region.

10. The organic light emitting display of claim 8, wherein the host A PL region overlaps a peak of the MLCT3 region of the dopant UV absorption region and does not overlap a peak of the MLCT1 region of the dopant UV absorption region, and
wherein the host B PL region overlaps the peak of the MLCT1 region of the dopant UV absorption region and does not overlap the peak of the MLCT3 region of the dopant UV absorption region.

11. The organic light emitting display of claim 8, wherein the host A PL region and the host B PL region overlap each other only in an overlap region between the MLCT1 region and the MLCT3 region of the dopant UV absorption region.

12. The organic light emitting display of claim 8, wherein the hosts of the fluorescent materials include a mixture of carbazole-based compound and anthracene-based compound.

13. The organic light emitting display of claim 8, wherein the emission layer includes a host region, a mixture region of the host and the dopant, and a dopant region.

14. The organic light emitting display of claim 8, wherein the dopant of the phosphorescent materials has a PL wavelength band of 380 nm to 780 nm.
